(19) United States
(12) Patent Application Publication
(10) Pub. No.: US 2011/0212622 A1
(43) Pub. Date: Sep. 1, 2011

(54) SURFACE TEXTURING USING A LOW QUALITY DIELECTRIC LAYER

(75) Inventors: Joel P. Desouza, Putnam Valley, NY (US); Harold J. Hovel, Katonah, NY (US); Daniel Inns, Palo Alto, CA (US); Jeehwan Kim, White Plains, NY (US); Devendra K. Sadana, Pleasantville, NY (US); Katherine L. Saenger, Ossining, NY (US)

(73) Assignee: INTERNATIONAL BUSINESS MACHINES CORPORATION, Armonk, NY (US)

(21) Appl. No.: 12/714,426

(22) Filed: Feb. 26, 2010

(51) Int. Cl. H01L 21/311

(52) U.S. Cl. 438/694; 257/E21.249

(57) ABSTRACT

A low cost method is described for forming a textured Si surface such as for a solar cell which includes forming a dielectric layer containing pinholes, anisotropically etching through the pinholes to form inverted pyramids in the Si surface and removing the dielectric layer thereby producing a high light trapping efficiency for incident radiation.

### BACKGROUND

The present invention relates to surface texturing to improve light trapping in solar cells, and more specifically, to low cost surface texturing of a Si containing substrate to form inverted pyramids using chemical etching and a low quality dielectric layer.

Texturing and anti-reflection coatings are commonly used to increase the efficiency of light absorption in solar cells. Upright pyramid formation on the surface of mono-crystalline silicon wafers is a standard technique for texturing the surface to maximize light absorption into a solar cell. It is well known that, by texturing a solar cell surface, photon utilization, light trapping or quantum efficiency can be improved by as much as 20% compared to a solar cell with a flat polished surface. Hemispherical reflectance of 10 to 13% has been reported from the upright pyramids formed by anisotropic chemical etching. The density of upright pyramids and their geometry both affect the light trapping efficiency. To achieve uniform and dense upright pyramids, isopropanol (IPA) can be added into alkaline etching solutions.

In order to achieve inverted pyramid patterns, photolithography followed by anisotropic etching is a standard sequence. Even if a more effective textured surface with less reflectance can be achieved by this method, the photolithography step adds to the cost of the process.

### BRIEF SUMMARY OF THE INVENTION

In accordance with the present invention, a method for forming a textured surface on a Si containing substrate is described comprising forming a dielectric layer on the surface having a plurality of pinholes through the dielectric layer, anisotropic etching the surface through the pinholes to form inverted pyramid patterns and removing the dielectric layer. One embodiment of the invention provides a random distribution of inverted pyramid patterns having a hemispherical reflectance of less than 13%.

### BRIEF DESCRIPTION OF THE SEVERAL VIEWS OF THE DRAWINGS

These and other features, objects, and advantages of the present invention will become apparent upon consideration of the following detailed description of the invention when read in conjunction with the drawing in which:

FIG. 1 is a cross-section view of a structure having a Si layer or Si containing layer and a porous oxide and/or nitride dielectric layer with a high density of pinholes thereon.

FIG. 2 is a cross-section view of a structure after etching the upper surface of a Si layer or of a Si containing layer through a porous oxide and/or nitride dielectric layer.

FIG. 3 is a cross-section view of the structure of FIG. 2 after removing the porous oxide and/or nitride layer.

### DETAILED DESCRIPTION

A method is described to form inverted pyramid patterns on a Si or Si containing surface with minimum process cost. The method offered does not require extensive etching of Si materials and a cost-inefficient photolithography step. The method for generating an inverted pyramid pattern on a Si surface is achieved through depositing one or more low quality porous dielectric layers on a Si surface followed by anisotropic etching of the Si surface with an alkaline solution where it penetrates the low quality porous dielectric layer or layers. A high density of pinholes having been formed in a low quality dielectric layer or layers is used as a mask for anisotropic etching. A random distribution of inverted pyramids are then formed in the Si or Si containing surface having a hemispherical reflectance of less than 13%.

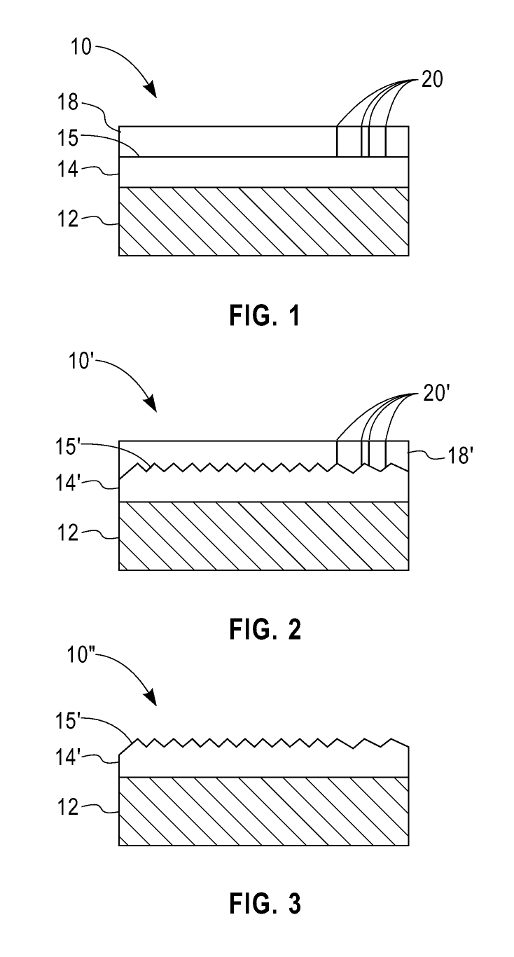

Referring now to the drawing, FIGS. 1 through 3 illustrate the process flow to form inverted pyramid patterns on a Si or Si containing surface. FIG. 1 is a cross-section view of structure 10 having a substrate 12 which may, for example, comprise Si, a Si containing material, a glass, a metal or a polymer. A layer 14 of Si or a Si containing crystalline material is formed over substrate 12. Layer 14 has an upper surface 15 which may be initially smooth. A smooth Si or Si-containing surface is a surface having a surface roughness of less than 1 nm root mean square (RMS). Surface 15, if layer 14 is Si, may have a (100) crystal orientation.

A dielectric layer 18 is formed on crystalline silicon surface 15 of layer 14. Dielectric layer 18 contains pores or pinholes 20 and functions as a mask layer for etching. Dielectric layer 18 may be low density, low quality, and/or porous and may be SiO₂, SiNₓ or combinations of SiO₂ and SiNₓ. Typically, dielectric oxides or nitrides deposited using plasma enhanced chemical vapor deposition (PECVD) are less dense than those formed by other methods such as by thermal oxidation, atomic layer deposition (ALD), low pressure chemical vapor deposition (LPCVD) and sputtering. In other words, PECVD oxides or nitrides may include more pores or pinholes 20 in dielectric layer 18. The density of pores or pinholes 20 in dielectric layer 18 may be greater than 10⁶ pinholes/cm² and can be controlled by manipulating the deposition parameters of PECVD. For example, PECVD deposition parameters of low temperature in the range from 25° C. to 250° C., low power density in the range from 1 mW/cm² to 100 mW/cm², and low pressure in the range from 10 mtorr. to 1000 mtorr. leads to the deposition of porous or low quality oxides/nitrides which include a high density of pores or pinholes 20. The other methods mentioned above can also be used as long as the density of pinholes can be greater than 10⁶ pinholes/cm².

FIG. 2 is a cross-section view of structure 10′ which is formed by chemically etching structure 10. Structure 10 with porous oxides/nitrides as dielectric layer 18 as shown in FIG. 1 may be dipped into an alkaline solution such as KOH, tetra methyl ammonium hydroxide (TMAH) or NH₃OH for a time in the range from 10 sec to 20 min to anisotropically etch surface 15 of layer 14 which may be originally smooth. The temperature of the anisotropic etching process, which includes the temperature of the etching solution, may be in the range from 23° C. for a slow etch rate to an aqueous alkaline solution boiling temperature of about 100° C. for a fast etch rate. The etching time of the anisotropic etching should be less than the time required for growing inverted pyramid patterns that impinge or overlap an adjacent inverted pyramid on the surface.

The etching solution passes or penetrates through pores or pinholes 20 in layer 18, widens up original pinholes 20 shown as 20′ in FIG. 2, and reaches surface 15 of layer 14 to anisotropically etch Si or Si containing surface 15 of layer 14 to form inverted pyramid patterns having a depth in the range from 100 nm to 10 μm and a width in the range from 200 nm to 20 μm. Therefore, increasing the density of pores or pinholes 20 in layer 18 in the range from 10⁶/cm² to 10⁸/cm² achieves a higher density of inverted pyramids in the same range from 10⁶ inverted pyramids/cm² to 10⁸ inverted pyramids/cm² since surface 15′ of layer 14′ is exposed to the etching solution through pores or pinholes 20′ in dielectric layer 18′ forming inverted pyramids. Dielectric layer 18 may have a thickness in the range from 10 nm to 100 nm. The thickness of dielectric layer 18 such as an oxide must be thick enough in the range from 10 nm to 100 nm so as not to be removed during the anisotropic etching process, and yet not too thick in the range from 100 nm to 1 μm prohibit the etching solution from penetrating through pinholes 20 in dielectric layer 18. After finishing anisotropic etching of Si surface 15′ comprised of inverted pyramid patterns, Si surface 15′ of layer 14′ is ready to serve as a textured surface for solar cell applications.

It should be noted that pinholes 20 in dielectric layer 18 are not necessarily physical openings in dielectric layer 18 at the time dielectric layer 18 is deposited. For example, some or all of pinholes 20 may comprise pinhole-sized regions in dielectric layer 18 that are less resistant than the rest of the dielectric layer to the anisotropic etch used to etch layer 14, with the result that some or all of physical openings 20′ would be formed at early stages of the anisotropic etch, rather than being present originally.

FIG. 3 is a cross-section view of structure 10″ after removing porous oxide and/or nitride layer 18′ shown in FIG. 2. Layer 18′ can be removed by etching with hydrofluoric acid followed by rinsing Si or Si containing surface 15′ with deionized (DI) water to provide a clean textured Si or Si containing surface 15′ comprised of inverted pyramid patterns.

While there has been described and illustrated a method for forming a textured Si surface comprised of inverted pyramid patterns via anisotropic etching through a porous dielectric layer containing pores or pinholes, it will be apparent to those skilled in the art that modifications and variations are possible without deviating from the broad scope of the invention which shall be limited solely by the scope of the claims appended hereto.

What is claimed is:

1. A method for forming a textured surface on a Si containing substrate comprising:
forming a dielectric layer on said surface having a plurality of pinholes through said dielectric layer;
anisotropic etching said surface through said pinholes to form inverted pyramid patterns; and
removing said dielectric layer to expose said textured surface of inverted pyramid patterns.

2. The method of claim 1, wherein said dielectric layer has a thickness in the range from 10 nm to 100 nm.

3. The method of claim 1, wherein said dielectric layer has a density of pinholes in the range from 10⁶/cm² to 10⁸/cm².

4. The method of claim 1, wherein some or all of said pinholes comprise pinhole-sized regions of dielectric material that are removed to form openings at an early stage of said anisotropic etching.

5. The method of claim 1, wherein said dielectric layer is selected from the group consisting of an oxide, nitride and combinations thereof.

6. The method of claim 5, wherein said dielectric layer is selected from the group consisting of silicon dioxide, silicon nitride, aluminum oxide, hafnium oxide and combinations thereof.

7. The method of claim 1, wherein said dielectric layer is formed by a process selected from the group consisting of PECVD, ALD, LPCVD and sputtering.

8. The method of claim 1, wherein said anisotropic etching includes etching with an alkaline solution.

9. The method of claim 8, wherein said alkaline solution is selected from the group consisting of KOH, TMAH and NH₃OH.

10. The method of claim 1, wherein said anisotropic etching occurs at a temperature in the range from 23° C. for a slow etch rate to an aqueous alkaline solution boiling temperature of about 100° C. for a fast etch rate.

11. The method of claim 1, wherein an etching time of said anisotropic etching is less than the time required for growing inverted pyramid patterns that impinge an adjacent inverted pyramid on said surface.
